(19) United States
(12) Patent Application Publication
(10) Pub. No.: US 2007/0222463 A1
(43) Pub. Date: Sep. 27, 2007

(54) Power conversion efficiency management

(76) Inventors: Jaber Abu Qahouq, Beaverton, OR (US); Lilly Huang, Portland, OR (US)

Correspondence Address: SCHWEGMAN, LUNDBERG, WOESSNER & KLUTH, P.A., P.O. BOX 2938, MINNEAPOLIS, MN, 55402, US

(21) Appl. No.: 11/387,395

(22) Filed: Mar. 23, 2006

(51) Int. Cl. G01R 27/08

(52) U.S. Cl. 324/712

(57) ABSTRACT

Some embodiments of the invention may operate to measure a feedback error signal change as an indication of efficiency associated with a power stage, and to select a determined power stage parameter value to increase the efficiency responsive to the feedback error signal change.

### TECHNICAL FIELD

Various embodiments described herein relate to the provision of power generally, including apparatus, systems, and methods used to manage the efficiency of power supplies and converters.

### BACKGROUND INFORMATION

The output error voltage in a power stage may be used to regulate the output voltage, perhaps by determining the duty cycle or switching frequency of the stage in order to regulate the output voltage. For example, under steady state conditions, such as constant load, input voltage, and ambient temperature, the conventional control loop may operate to force the output voltage to match the reference voltage, such that the output error voltage tends toward zero. In this case, the output error voltage is substantially dedicated to regulating the output voltage.

### BRIEF DESCRIPTION OF THE DRAWINGS

FIG. 1 is a block diagram of apparatus and systems for power conversion efficiency management according to various embodiments of the invention.

FIG. 2 is a flow diagram illustrating several methods for power conversion efficiency management according to various embodiments of the invention.

FIG. 3 is a flow diagram illustrating additional methods for power conversion efficiency management according to various embodiments of the invention.

FIG. 4 is a block diagram of an article for power conversion efficiency management according to various embodiments.

### DETAILED DESCRIPTION

Power supply designers are typically concerned with two aspects of supply performance: output regulation, and efficiency. While conventional designs make use of an error voltage (Ve) to dynamically improve regulation, efficiency often depends on static design parameters. In the embodiments described herein, efficiency may be improved in a dynamic fashion by measuring a change in an error signal (e.g., ΔVe, or the change in error voltage, or ΔIe, or the change in error current), and adjusting selected supply parameters in response thereto.

Thus, while the error voltage may remain substantially constant, its value depends not only on the difference between the input voltage and the output voltage (via circuit gain), but on the power losses in the power conversion path. Greater losses mean that less energy is delivered to the output, and thus, efficiency may be reduced. Here, the change in the error signal is used as indication to determine in which direction power stage parameters should be changed (e.g., incremented or decremented), so that the error signal can be used to indicate power losses and improve operating efficiency, reducing the losses.

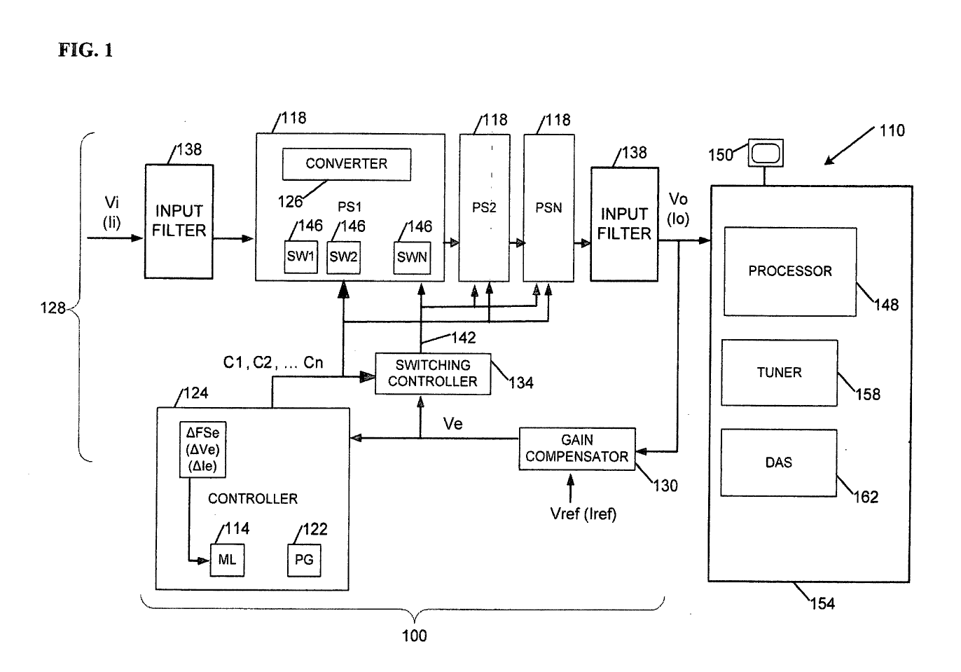

FIG. 1 is a block diagram of apparatus 100 and systems 110 for power conversion efficiency management according to various embodiments of the invention. The apparatus 100 may include measurement logic 114 to measure a feedback error signal change ΔFSe (e.g., comprising an output voltage error change ΔVe) as an indication of efficiency in one or more power stages 118. The apparatus 100 may also include performance governor logic 122 coupled to the power stages 118, such that the performance governor logic 122 is used to select one or more determined power stage control parameter values C1, C2, . . . , CN to increase efficiency responsive to the feedback error signal change ΔFSe. Examples of determined power stage control parameter values C1, C2, . . . , CN include selecting a particular switching frequency or switching dead time, selecting an input voltage or an output voltage, or selecting a number of active switches, or active power stages, among others. The measurement logic 114 and the performance governor logic 122 may form a portion of an adaptive controller 124.

Essentially, a control technique is disclosed herein that can be used to dynamically reduce power consumption by adaptively tracking the change in feedback error signal. Here, the change in a feedback error signal is used as an indicator of efficiency (i.e., as an increase or decrease in power loss when power is provided in various applications). By monitoring the feedback error signal change and using it as an indication of efficiency, the trend of power consumption and efficiency for the power stages 118 can be predicted. It is then possible to use the trend information to dynamically select proper control parameters or modify the existing mode of operation in order to reduce power loss, even in the face of adverse conditions, such as a non-constant input voltage, variable loading, and component parameter instability.

Various embodiments may include a wide variety of mechanisms to supply power, convert power, and invert power. For example, the power stages 118 may-include one or more converters 126, such as buck converters, boost converters, AC-AC converters, AC-DC converters, DC-DC converters, and DC-AC converters, among others. That is, while a simple DC-DC voltage regulator 128 is shown in FIG. 1, any number of circuit topologies may be used.

In some embodiments, then, the apparatus 100 may include one or more gain compensators 130 to couple to the measurement logic 114, and to receive a reference voltage Vref. The apparatus 100 may also include one or more switching frequency controllers 134 coupled to the performance governor logic 122, and/or one or more input filters 138 coupled to the power stages 118.

While it should be understood that the feedback error signal change ΔFSe may comprise an error voltage change or an error current change, the example of an error voltage change will be used for the balance of this document in order to maintain simplicity. Thus, the reader should understand that the terms “voltage” and “current” can be used interchangeably throughout this document, and in the figures.

Consider the situation where the output voltage Vo is regulated to assume a value that approximates a reference voltage, Vref, while the power stages 118 are supplied by an input voltage, Vi. Then the output error voltage Ve may be defined as the difference between the output voltage Vo and the reference voltage Vref, after being adjusted according to the action of gain or/and compensation transfer networks, which may include the power stages 118 and the input filters 138 as shown in FIG. 1.

The determined power stage control parameter values C1, C2, . . . Cn are defined as a set of control parameter values which may be adjusted to reduce the power losses of a power stage. Thus, the determined power stage control parameter values C1, C2, . . . Cn may comprise a number of power stage control variables, such as dead time, switching frequency, and input voltage from a previous stage. The control signal 142 may be used to directly manage the power processing and/or switching activity of power switching devices 146 in the power stages 118, including their switching frequency.

In practice, some-embodiments may operate as follows. While an error signal, such as the error voltage Ve, may be used to determine the duty cycle or/and switching frequency of power stage switches 146, including turning the switches 146 ON for a certain amount of time to deliver the necessary energy to the load and regulate the output voltage Vo, in many embodiments the feedback error signal change ΔFSe, such as ΔVe, may be used to indicate the change in the direction of power loss in the power stages 118 while adaptively varying the determined power stage control parameter values C1, C2, . . . Cn to reduce power losses, and increase efficiency. The determined power stage control parameter values C1, C2, . . . Cn include power switch dead time, switching frequency, input/output voltage, number of turned ON switches or power stages, among others. Thus, monitoring the change in the error signal ΔFSe, such as ΔVe, may reveal additional information that indicates the conversion power loss in addition to the required duty cycle/conversion ratio (gain). This indication of efficiency, or power loss, can therefore be used to adaptively reduce power losses and increase efficiency.

In many power stages, when a substantially steady state condition exist (e.g., a constant load, constant input voltage, and/or constant environmental temperature, etc.), the control loop operates to force the output voltage to be the same as the reference voltage. However, as mentioned previously, the error voltage Ve depends on the difference between the input voltage and the output voltage, as well as the power losses in the conversion path. Using the mechanism disclosed herein, determined power stage control parameter values C1, C2, . . . Cn can be adaptively adjusted (e.g., incremented and decremented) in response to the measured change in Ve to find values that provide reduced power losses, increasing efficiency. In some embodiments, this may occur by minimizing the steady state error voltage Ve, in a buck converter, for example. Power loss, and therefore efficiency, may vary under different conditions due to component parasitics.

In some embodiments, efficiency may be determined using the following relationship:

$$Efficiency = \frac{{P}_{o}}{{P}_{i n}} = \frac{{P}_{i n} - {P}_{sw} - {P}_{cond} - {P}_{other}}{{P}_{i n}} ,$$

where Pin=input power; Psw∝f(Vsw²,fsw) [switching losses as a function of the voltage across the switch (Vsw), which sometimes may be equal to Vo; also a function of switch parasitic capacitance, and other parasitics];

Pcond∝f(I², R) [conduction losses as a function of switch on-resistance and other component resistance]; and Pₒₜₕₑᵣ=other power losses, such as those from control logic and drivers. According to some embodiments, the efficiency may be determined in other ways, that is, by using different relationships, as one of ordinary skill in the art would appreciate based at least on the teachings provided herein.

Power loss, including switching and conduction losses, is often lowest when Ve is minimum, using less input power for the same delivered output power, and thus reducing power loss. It should be noted, then, that a change in ΔVe may be used to minimize Ve, resulting in reduced losses. However, it is often beneficial to maintain a value of Ve sufficient to ensure output regulation. Thus, the direction in which Ve changes (the direction of ΔVe) can be used as an indication of the direction to change the determined power stage control parameter values C1, C2, . . . Cn (e.g., whether to increment or decrement them), and Ve may be targeted for decreasing (or increasing, depending on modulation direction), which results in reduced power losses and higher conversion efficiency.

Other embodiments may be realized. For example, a system 110, comprising any number of electronic devices, such as a power supply, or a laptop or desktop computer, may include one or more apparatus 100 as described above. The system 110 may also include a processor 148 and one or more displays 150 to receive power from the power stages 118.

In some embodiments, the system 110 may include a computer motherboard 154 to receive power from the power stage(s) 118 (e.g., in a computer or workstation implementation), a television tuner 158 to receive power from the power stage(s) 118 (e.g., in a television implementation), and/or a medical data acquisition system 162 to receive power from the power stage(s) 118 (e.g., in a medical device implementation, such as an ultrasound imaging unit, or an EKG machine). That is, the motherboard 154, the television tuner 158, and the data acquisition system 162 may be used alone, or in conjunction with each other.

Any of the components previously described can be implemented in a number of ways, including simulation via software. Thus, the apparatus 100; systems 110; measurement logic 114; power stages 118; performance governor logic 122; adaptive controller 124; converter 126; DC-DC voltage regulator 128; gain compensator 130; switching frequency controller 134; input filters 138; control signal 142; power switching devices 146; processor 148; display 150; motherboard 154; television tuner 158; medical data acquisition system 162; determined power stage control parameter values C1, C2, . . . , CN; feedback error signal change ΔFSe; output error voltage Ve; input voltage Vi; output voltage Vo; and reference voltage Vref may all be characterized as “modules” herein.

Such modules may include hardware circuitry, single and/or multi-processor circuits, memory circuits, software program modules and objects, and/or firmware, and combinations thereof, as desired by the architect of the apparatus 100 and systems 110, and as appropriate for particular implementations of various embodiments. For example, such modules may be included in a system operation simulation package, such as a software electrical signal simulation package, a power usage and distribution simulation package, a capacitance-inductance simulation package, a power/heat dissipation simulation package, a signal transmission-reception simulation package, and/or a combination of software and hardware used to operate, or simulate the operation of various potential embodiments.

It should also be understood that the apparatus and systems of various embodiments can be used in applications other than DC-DC converters and power supplies, and thus, various embodiments are not to be so limited. The illustrations of apparatus 100 and systems 110 are intended to provide a general understanding of the structure of various embodiments, and they are not intended to serve as a complete description of all the elements and features of apparatus and systems that might make use of the structures described herein.

Applications that may include the novel apparatus and systems of various embodiments include electronic circuitry used in high-speed computers, communication and signal processing circuitry, single and/or multi-processor modules, single and/or multiple embedded processors, and application-specific modules, including multilayer, multi-chip modules. Such apparatus and systems may further be included as sub-components within a variety of electronic systems, such as televisions, cellular telephones, personal computers, switches, hubs, routers, modems, workstations, radios, video players, audio players, medical devices, vehicles, and others.

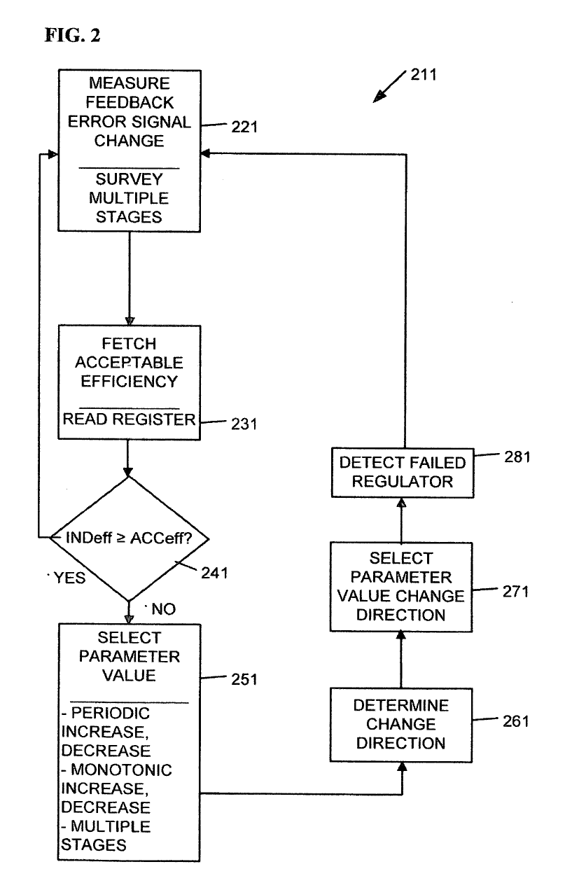

Some embodiments may include a number of methods. For example, FIG. 2 is a flow diagram illustrating several methods 211 for power conversion efficiency management according to various embodiments of the invention. For example, a method 211 begin with measuring a feedback error signal change as an indication of efficiency associated with a power stage at block 221. In some embodiments, the method 211 may include surveying a plurality of power stages to measure corresponding feedback error signal changes as an indication of efficiency associated with each of the surveyed power stages.

In some embodiments, the method 211 may include fetching or otherwise retrieving a value of an acceptable efficiency with respect to the power stage at block 231. For example, the value may be retrieved by reading a register to determine an acceptable efficiency associated with the power stage. The method 211 may also include selecting a trial determined power stage parameter value if the indication of efficiency (INDeff) is less than the acceptable efficiency ACCeff at blocks 241 and 251. Otherwise, if the indication of efficiency INDeff is greater than or equal to the acceptable efficiency ACCeff, the method 211 may continue at block 221.

The selection of a trial determined power stage parameter value at block 251 may occur in a number of ways. For example, selecting the determined power stage parameter value to increase the efficiency of the power stage responsive to the feedback error signal change (such as an error voltage change if error voltage Ve tracking is used to optimize switching frequency or dead time in a digital controller to improve the operating efficiency of a buck converter, for example), may be effected by periodically incrementing and/or decrementing the determined power stage parameter value to search for a new power stage parameter value to increase the efficiency.

In some embodiments, selecting the determined power stage parameter value to increase the efficiency responsive to the feedback error signal change may occur by selecting a series of monotonically decreasing (or monotonically increasing) power stage parameter values to search for a new power stage parameter value to increase the efficiency. Multiple power stages may be surveyed to select a plurality of associated determined power stage parameter values to increase the efficiency associated with one or more of the power stages.

In some embodiments, the method 211 may include determining the direction of change in the feedback error signal change at block 261, and then selecting a change direction of the determined power stage parameter based on the change direction of the feedback error signal change at block 271. For example, if the feedback error signal changes in a positive direction, a positive change in the determined power stage parameter value may be made (or a negative change, in some embodiments). Similarly, if the feedback error signal changes in a negative direction, a negative change in the determined power stage parameter value may be made (or a positive change, in some embodiments). In some cases, the method 211 may include detecting a failed regulator coupled to the power stage based on the feedback error signal change at block 281.

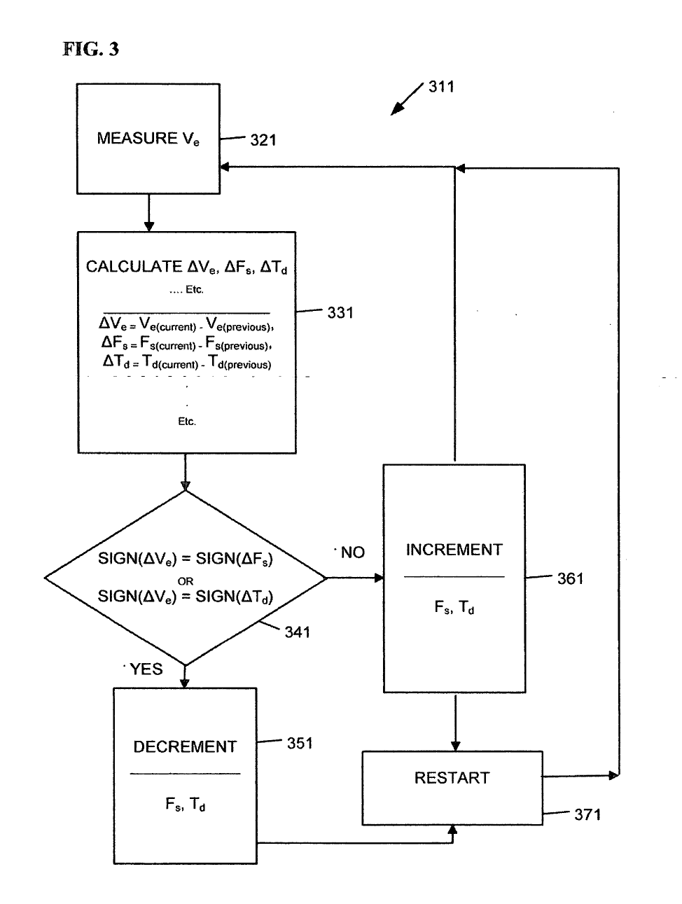

FIG. 3 is a flow diagram illustrating additional methods 311 for power conversion efficiency management according to various embodiments of the invention. For example, a method 311 may begin with measuring Ve (the current error voltage) at block 321. The method 311 may continue at block 331 with calculating the change in the error voltage Ve as the current error voltage Ve minus the previously-measured error voltage Ve. The change in several other parameters may also be calculated, including any of the determined power stage control parameter values mentioned previously, such as the change in switching frequency ΔFs, and the change in switching dead time ΔTd.

As mentioned previously, the direction in which the error voltage changes (e.g., the sign(ΔVe)) can be used to determine which direction to change one or more determined power stage parameter values. For example, a determination can be made at block 341 as to whether the direction of change in the error voltage is the same as the direction of change in the switching frequency (e.g., did ΔVe increase as switching frequency Fs increased, or did ΔVe decrease as switching frequency Fs decreased?). If so, then the method 311 may continue with block 351, to decrement the switching frequency Fs. Similarly, a determination can be made as to whether the direction of change in the error voltage is the same as the direction of change in the switching dead time (e.g., did ΔVe increase as switching dead time Td increased, or did ΔVe decrease as switching dead time Td decreased?). If so, then the method 311 may continue with block 351, to decrement the switching dead time Td.

On the other hand, a determination can be made at block 341 as to whether the direction of change in the error voltage was in a different direction than that of the switching frequency (e.g., did ΔVe increase as switching frequency Fs decreased, or did ΔVe decrease as switching frequency Fs increased?). If so, then the method 311 may continue with block 361, to increment the switching frequency Fs. Similarly, a determination can be made as to whether the direction of change in the error voltage is different than the direction of change in the switching dead time (e.g., did ΔVe increase as switching dead time Td decreased, or did ΔVe decrease as switching dead time Td increased?). If so, then the method 311 may continue with block 361, to increment the switching dead time Td. In either case, after incrementing or decrementing the switching frequency Fs or switching dead time Td, the method 311 may go on to restart at block 371, and (perhaps after a time delay at block 371) the method 311 may continue with a new measurement sequence at block 321.

It should be noted that the methods described herein do not have to be executed in the order described, or in any particular order. Moreover, various activities described with respect to the methods identified herein can be executed in repetitive, simultaneous, serial, or parallel fashion. Information, including parameters, commands, operands, and other data, can be sent and received in the form of one or more carrier waves.

Upon viewing the content of this disclosure, one of ordinary skill in the art will understand the manner in which a software program can be launched from a computer-readable medium in a computer-based system to execute the functions defined in the software program. One of ordinary skill in the art will further understand the various programming languages that may be employed to create one or more software programs designed to implement and perform the methods disclosed herein. The programs may be structured in an object-orientated format using an object-oriented language such as Java, Smalltalk, or C++. Alternatively, the programs can be structured in a procedure-orientated format using a procedural language, such as assembly or C. The software components may communicate using any of a number of mechanisms well known to those skilled in the art, such as application program interfaces or interprocess communication techniques, including remote procedure calls. The teachings of various embodiments are not limited to any particular programming language or environment, including Hypertext Markup Language (HTML) and Extensible Markup Language (XML). Thus, other embodiments may be realized.

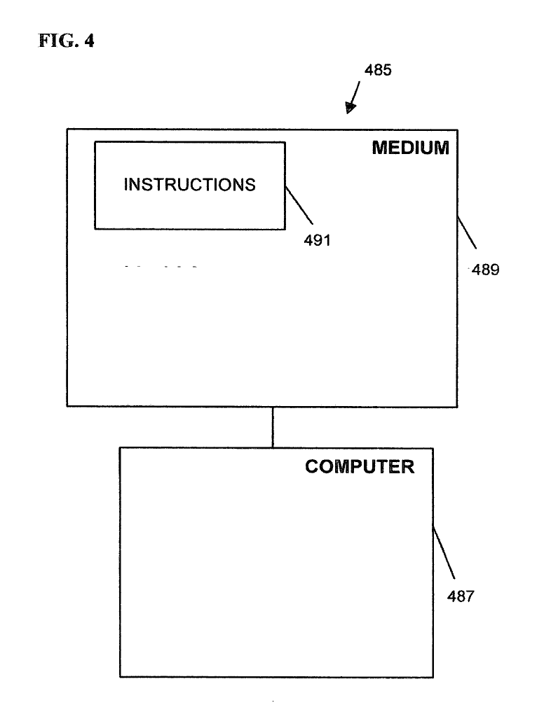

FIG. 4 is a block diagram of an article 485 for power conversion efficiency management according to various embodiments, such as a computer, a memory system, a magnetic or optical disk, some other storage device, and/or any type of electronic device or system. The article 485 may include a computer 487 (having one or more processors) coupled to a computer-readable medium 489, such as a memory (e.g., fixed and removable storage media, including tangible memory having electrical, optical, or electromagnetic conductors) or a carrier wave, having associated information 491 (e.g., computer program instructions and/or data), which when executed by the computer 487, causes the computer 487 to perform a method including such actions as measuring an feedback error signal change as an indication of efficiency associated with a power stage, and selecting a determined power stage parameter value to increase the efficiency responsive to the feedback error signal change.

Further activities may include detecting a failed regulator coupled to the power stage based on the feedback error signal change, and surveying multiple power stages, including the power stage, to select a plurality of associated determined power stage parameter values to increase efficiency associated with the multiple power stages. Other activities may include any of those forming a portion of the methods illustrated in FIGS. 2 and 3, and described above.

Implementing the apparatus, systems, and methods disclosed herein may operate to reduce power losses of power converters and regulators used in computing and communications platforms, among others, in both stationary and mobile devices. Battery life may also be extended over more conventional solutions due to higher efficiency under varying load conditions.

The accompanying drawings that form a part hereof show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

1. An apparatus, including:
measurement logic to measure a feedback error signal change as an indication of efficiency in a power stage; and
performance governor logic to select a determined power stage control parameter to increase the efficiency responsive to the feedback error signal change.

2. The apparatus of claim 1, wherein the power stage includes:
a DC-DC converter.

3. The apparatus of claim 1, wherein the determined power stage control parameter includes at least one of a switching dead time, a switching frequency, an input voltage, an output voltage, a number of active switches, and a number of active power stages.

4. The apparatus of claim 1, further including:
a gain compensator coupled to the measurement logic.

5. The apparatus of claim 1, further including:
a plurality of power stages coupled to the performance governor logic.

6. The apparatus of claim 5, wherein the feedback error signal change comprises an output voltage error change.

7. A system, including:
measurement logic to measure a feedback error signal change as an indication of efficiency in a power stage;
performance governor logic to select a determined power stage control parameter to increase the efficiency responsive to the feedback error signal change; and
a display to receive power from the power stage.

8. The system of claim 7, further including:
a computer motherboard to receive power from the power stage.

9. The system of claim 7, further including:
a television tuner to receive power from the power stage.

10. The system of claim 7, further including:
a medical data acquisition system to receive power from the power stage.

11. The system of claim 7, wherein the power stage includes at least one of a buck converter and a boost converter.

12. A method, comprising:
measuring a feedback error signal change as an indication of efficiency associated with a power stage; and
selecting a determined power stage parameter value to increase the efficiency responsive to the feedback error signal change.

13. The method of claim 12, further including:
selecting a change direction of the determined power stage parameter based on a change direction of the feedback error signal change.

14. The method of claim 12, further including:
reading a register to determine an acceptable efficiency associated with the power stage.

15. The method of claim 12, further including:
selecting a trial determined power stage parameter value if the efficiency is less than an acceptable efficiency.

16. The method of claim 12, further including:
periodically incrementing the determined power stage parameter value to search for a new power stage parameter value to increase the efficiency.

17. The method of claim 12, further including:
selecting a series of monotonically decreasing power stage parameter values to search for a new power stage parameter value to increase the efficiency.

18. A computer-readable medium having instructions stored thereon which, when executed by a computer, cause the computer to perform a method comprising:
measuring a feedback error signal change as an indication of efficiency associated with a power stage; and
selecting a determined power stage parameter value to increase the efficiency responsive to the feedback error signal change.

19. The computer-readable medium of claim 18, wherein the instructions, when executed by the computer, cause the computer to perform a method comprising:
detecting a failed regulator coupled to the power stage based on the feedback error signal change.

20. The computer-readable medium of claim 18, wherein the instructions, when executed by the computer, cause the computer to perform a method comprising:
surveying multiple power stages, including the power stage, to select a plurality of associated determined power stage parameter values to increase the efficiency associated with the multiple power stages.
